(19) United States
(12) Patent Application Publication
(10) Pub. No.: US 2015/0035813 A1
(43) Pub. Date: Feb. 5, 2015

(54) DRIVE CIRCUIT OF ORGANIC LIGHT EMITTING DISPLAY AND OFFSET VOLTAGE ADJUSTMENT UNIT THEREOF

(71) Applicant: INTEGRATED SOLUTIONS TECHNOLOGY INC., TAIPEI CITY (TW)

(72) Inventor: CHIA CHENG LEI, NEW TAIPEI CITY (TW)

(73) Assignee: INTEGRATED SOLUTIONS TECHNOLOGY INC., TAIPEI CITY (TW)

(21) Appl. No.: 14/070,515

(22) Filed: Nov. 2, 2013

(30) Foreign Application Priority Data
Aug. 2, 2013 (TW) 102127753

(51) Int. Cl. G09G 3/32; H03F 3/45

(52) U.S. Cl. CPC G09G 3/3208; H03F 3/45071; H03F 2203/45112
USPC 345/205; 330/261

(57) ABSTRACT

A drive circuit of an organic light emitting display and an offset voltage adjustment unit thereof are provided. The offset voltage adjustment unit can be used in an operational amplifier of the drive circuit having a differential input stage, a bias stage, and an output stage. The offset voltage adjustment unit coupled between the bias stage and a ground including a resistor string and a plurality of latch units. The resistor string has a first-end, a second-end, and a plurality of resistors series-connected between the first-end and the second-end forming a plurality of junctions. The latch units are coupled between the junctions and the ground, respectively. The latch units are sequentially conducted to adjust a bias current of the bias stage according to a control signal. The latch units enter a latch state upon receiving a latch signal to calibrate an output offset voltage of the operational amplifier.

### BACKGROUND

1. Technical Field

The instant disclosure relates to an operational amplifier; in particular to an offset voltage adjustment unit for calibrating an offset voltage of the operational amplifier and a drive circuit of an organic light emitting display using the same.

2. Description of Related Art

Operational amplifiers have electrical characteristic of high input impedance but low output impedance, and the circuit thereof can be configured to implement various circuit application including comparator, amplifier, buffer, filter, analog-to-digital converter (ADC), a digital to analog converter (DAC), and the like, hence operational amplifiers have been widely used in a display such as the drive circuit of liquid crystal display (LCD) or organic light emitting display (OLED). However, owing to the technical limitations on current semiconductor manufacturing process and integrated circuit development, process variations (for example, parameter variation), and working environment (for example, operation voltage, temperature), the operational amplifier induces an offset voltage in the output voltage in operation leading to a phenomenon known as the zero drift and generates common mode signals affecting the output of the operational amplifier.

Specifically, when the non-inverting signal input and inverting signal input of the operational amplifier are at zero voltage level, the output voltage of the operational amplifier not only is not at zero voltage level but also is turned into a time-varying voltage signal. Accordingly, when the operational amplifier has a strong tendency generating offset voltage, the output thereof would affect the subsequent circuit operation. For example, given an operational amplifier is configured as a buffer for driving the drive circuit in a pixel array of the OLED. When zero drift phenomenon occurs, the gray level voltage which drives the display panel would become biased and affects the display quality.

Please refer to FIGS. 1A to 1D. FIGS. 1A to 1D show a schematic diagram illustrating conventional compensation circuits for an operational amplifier, in which the compensation circuit is used for reducing output offset voltage.

FIG. 1A illustrates an auto-zero compensation amplifier circuit using auto-zero technology. The auto-zero compensation amplifier circuit uses a capacitor C1 to store the offset voltage which is detected by feedback circuit. Then, the input signal is correspondingly compensated to eliminate potential effect of the offset voltage. However, larger capacitor is required using the auto-zero technology so as to prevent errors caused by switching operation of the switching circuit. FIG. 1B illustrates a chopper amplifier circuit. The chopper amplifier circuit converts a DC bias voltage signal into a high frequency AC voltage signal through fast switching operations. The high frequency AC signal is subsequently filtered by a low-pass filter circuit. Although, the chopper amplifier can attenuate DC bias voltage and reduce the flicker noise generated by the complementary metal-oxide-transistor, but fast switching greatly increases power consumption.

FIG. 1C illustrates the circuitry of a conventional analog offset cancellation circuit. The analog offset cancellation includes a plurality of large capacitors for storing the compensation voltage and an analog control circuit for attenuating the offset voltage of the operational amplifier. FIG. 1D illustrates a digital offset cancellation which digitally compensates the offset voltage. However, both analog offset cancellation and digital offset cancellation requires large circuitry area for the placement of the compensation circuit. Hence, when the operational amplifier is applied in a large integrated circuit, e.g. the drive circuit of OLED, a significant portion of the chip would be occupied, and the overall consumption increases as well.

### SUMMARY

An exemplary embodiment of the instant disclosure provides an offset voltage adjustment unit and a drive circuit of an organic light emitting display. The offset voltage adjusting unit can be built into the drive circuit of operational amplifier. The offset voltage adjusting unit can be configured to adjust a bias current generated by a bias circuit of operational amplifier according to the output voltage of the operational amplifier so as to adjust an output offset voltage of the operational amplifier generated due to variation in the ambient temperature variation, the operating voltage, or process factors.

An exemplary embodiment of the instant disclosure provides a drive circuit of an organic light emitting display. The drive circuit includes a digital-to-analog conversion unit, a control unit, and an output unit. The control unit is coupled to the digital-to-analog conversion unit. The output unit has a plurality of buffer units, and each of the buffer units includes an operational amplifier and a calibration unit. The operational amplifier has a differential input stage, a bias stage, an output stage, and an offset voltage adjustment unit. The offset voltage adjustment unit is coupled between the bias stage and a ground. The offset voltage adjustment unit includes a resistor string and a plurality of latch units. The offset voltage adjustment unit is configured for adjusting a bias current generated by the bias stage. The calibration unit is coupled between the latching units and an output terminal of the operational amplifier. The calibration unit operatively controls the operations of the latch units so as to adjust the bias current of the bias stage according to an output voltage of the operational amplifier. The control unit inserts a calibration period in a driving cycle, during which the control unit enables the calibration unit to perform a calibration procedure. The calibration unit operatively causes the latch units to enter a latch state to calibrate an output offset voltage of the operational amplifier at the completion of the calibration procedure.

According to one exemplary embodiment of the instant disclosure, the resistor string has a first-end and a second-end. The first-end and the second-end are respectively coupled to the bias stage, wherein a plurality of resistors is series-connected between the first-end and the second-end to form a plurality of junctions. The latch units are coupled between the junctions and the ground, respectively.

The calibration unit sequentially conducts the latch units to adjust the bias current during the calibration period, and the calibration unit calibrates the output offset voltage of the operational amplifier, such that the output offset voltage approaches zero voltage level.

According to one exemplary embodiment of the instant disclosure, when the calibration unit detects that the output voltage of the operational amplifier changes from a high voltage level to a low voltage level or from a low voltage level to a high voltage level, the calibration unit outputs a latch signal causing the latch units to enter the latch state so that one of the latch units selected maintains conduction.

An exemplary embodiment of the instant disclosure provides an offset voltage adjustment unit for an operational amplifier. The operational amplifier has a differential input stage, a bias stage, and an output stage. The offset voltage adjustment unit is coupled between the bias stage and a ground. The offset voltage adjustment unit includes a resistor string and a plurality of latch units. The resistor string has a first-end and a second-end, which are respectively coupled to the bias stage. A plurality of resistors is series-connected between the first-end and the second-end to form a plurality of junctions. A plurality of latch units is respectively coupled between the junctions and the ground. The latch units is configured to sequentially conduct responsive to a control signal to adjust a bias current generated by the bias stage and to enter a latch state upon receiving a latch signal so as to calibrate an output offset voltage of the operational amplifier.

According to one exemplary embodiment of the instant disclosure, the latch unit includes a first transistor, a second transistor, and a storage capacitor. A source of the first transistor is configured for receiving the control signal, and a gate of the first transistor is configured for receiving the latch signal. A drain of the second transistor is coupled the junctions formed between the resistors. A source of the second transistor is coupled to the ground. A gate of the second transistor is coupled to a drain of the first transistor. The storage capacitor is coupled between the gate of the second transistor and the ground.

To sum up, an exemplary embodiment of the instant disclosure provides an offset voltage adjustment unit and a drive circuit of an organic light emitting display. The offset voltage adjustment unit can be configured for calibrating the output offset voltage generated due to the operating ambient temperature, source voltage, or process factors of the operational amplifier. The offset voltage adjustment unit can sequentially adjust the bias current generated by the bias circuit of the operational amplifier according to output voltage of the operational amplifier. Meanwhile, the offset voltage adjustment unit can record the operational amplifier calibration settings in the calibration process and stabilize the operational amplifier operation.

Accordingly, the impact of the output offset voltage on the operation of OLED can be prevented and improve the display quality of OLED. The offset voltage adjusting unit can be built-in in the operational amplifier without needing additional compensation circuit. Thus, it can greatly save the required chip area and reduce the overall power dissipation of the drive circuit.

In order to further understand the techniques, means and effects of the instant disclosure, the following detailed descriptions and appended drawings are hereby referred, such that, through which, the purposes, features and aspects of the instant disclosure can be thoroughly and concretely appreciated; however, the appended drawings are merely provided for reference and illustration, without any intention to be used for limiting the instant disclosure.

### BRIEF DESCRIPTION OF THE DRAWINGS

The accompanying drawings are included to provide a further understanding of the instant disclosure, and are incorporated in and constitute a part of this specification. The drawings illustrate exemplary embodiments of the instant disclosure and, together with the description, serve to explain the principles of the instant disclosure.

FIGS. 1A˜1D show conventional compensation circuits for operational amplifier;

FIG. 2 is a schematic diagram of the circuitry of an organic light emitting display in accordance with an embodiment of the instant disclosure;

FIG. 3 is a schematic diagram of a buffer unit in accordance with an embodiment of the instant disclosure;

FIG. 4 is a diagram illustrating an operation of a drive circuit of an organic light emitting display in accordance with an embodiment of the instant disclosure;

FIG. 5 is a detailed schematic view of an operational amplifier in accordance with an embodiment of the instant disclosure;

FIG. 6 is a schematic diagram of a latch unit in accordance with an embodiment of the instant disclosure; and

FIG. 7 is a schematic diagram of a calibration unit w in accordance with an embodiment of the instant disclosure.

### DESCRIPTION OF THE EXEMPLARY EMBODIMENTS

Reference will now be made in detail to the exemplary embodiments of the instant disclosure, examples of which are illustrated in the accompanying drawings. Wherever possible, the same reference numbers are used in the drawings and the description to refer to the same or like parts.

The instant disclosure provides an offset voltage adjustment unit. The offset voltage adjusting unit is configured for instantly adjusting a bias current of an operational amplifier according to an output voltage of the operational amplifier so as to calibrate the output offset voltage generated by the operational amplifier due to variations in the ambient temperature, the operating voltage, or process factors. Accordingly, the efficiency of the operational amplifier can be increased, while the power consumption of the offset compensation circuit can be reduced.

The instant embodiment illustrates the circuit operation of the offset voltage adjustment unit in the operational amplifier that is applied in the drive circuit of the organic light emitting display. However, the offset voltage adjustment unit can also be applied to the drive circuit of other display (e.g., liquid crystal display) or other operational amplifier applications. It should be appreciated that the instant disclosure is not limited. In addition, the circuit architecture, operation system and operation theory of the organic light emitting display and the operational amplifier should be well known to those skilled in the art, and hereinafter the description elaborates about the instant disclosure.

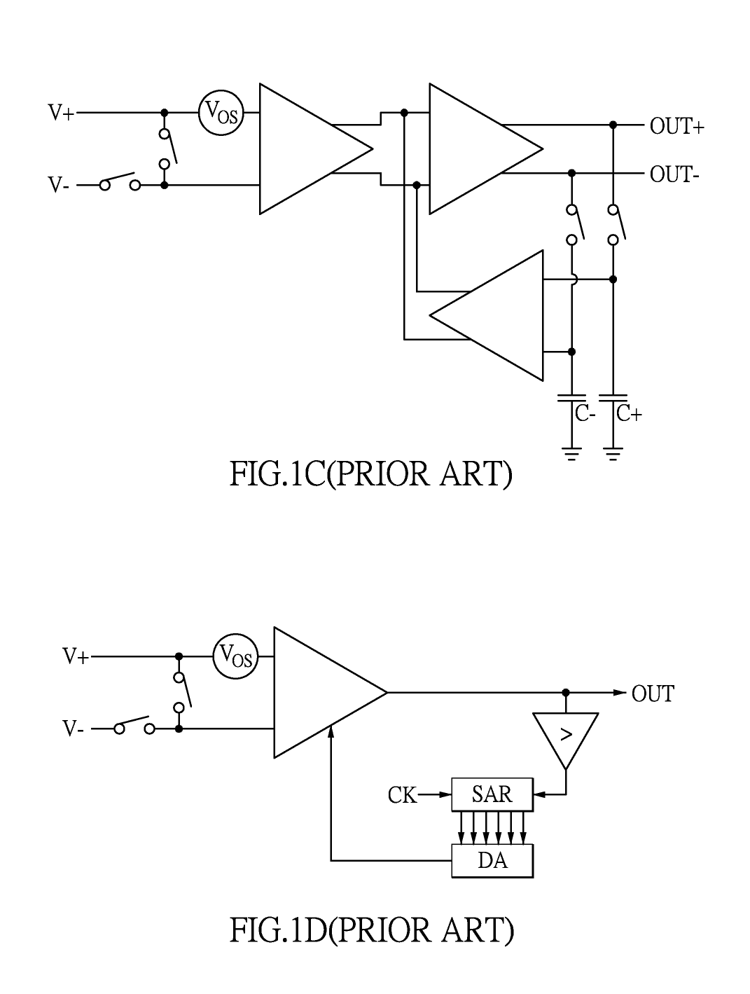

Please refer to FIG. 2, which shows a schematic diagram illustrating the circuitry of an organic light emitting display in accordance with an exemplary embodiment of the instant disclosure. The organic light emitting display 1 includes a drive circuit 10 and an organic light emitting display panel 20. The drive circuit 10 is coupled to the organic light emitting display panel 20. During each driving cycle, the drive circuit 10 operatively drives organic light emitting units on the organic light emitting display panel 20 to display an image according to an image data.

In the instant embodiment, the drive circuit 10 includes a resistor string unit 11, a digital-to-analog conversion unit 13, a control unit 15, and an output unit 17. The resistor string unit 11 is coupled to the digital-to-analog conversion unit 13. The digital-to-analog conversion unit 13 is coupled to the output unit 17. The resistor string unit 11, the digital-to-analog conversion unit 13, and the output unit 17 are respectively coupled to the control unit 15. The output unit 17 is coupled to the organic light emitting display panel 20.

The organic light emitting display panel 20 has a plurality of switch units 21 and an M×N pixel array. The pixel array includes a plurality of pixel units 23 arranged in a matrix manner, wherein M and N are positive integers. The switch units 21 are respectively coupled to the pixel units 23.

Each of the pixel units 23 comprises of three subpixels. The three subpixels include red subpixel R, green subpixel G and blue subpixel B. Each row is arranged to have the same subpixel, while each column has red sub-pixel R, green sub-pixel G and blue sub-pixel in succession. The red subpixel R, green sub-pixel G, and blue sub-pixel B are implemented by organic light emitting diodes.

Each of the switch units 21 includes a red pixel switch 211, a green pixel switch 213, and a blue pixel switch 215. The red pixel switch 211 is coupled between the output unit 17 and the red subpixel R of the pixel unit 23. The green pixel switch 213 is coupled between the output unit 17 and the green subpixel G of the pixel unit 23. The blue pixel switch 215 is coupled between the output unit 17 and the blue subpixel B of the pixel unit 23. The control unit 15 operatively controls the operations of the red pixel switch 211, the green pixel switch 213, and the blue pixel switch 215. In the instant embodiment, the red pixel switch 211, the green pixel switch 213, and the blue pixel switch 215 are implemented by the NMOS transistor.

Specifically, a gate of each NMOS is coupled to the control unit 15 for receiving clock signals CK_R, CK_G, and CK_B. A source of each NMOS is coupled to the output unit 17. A drain of each NMOS is coupled to the corresponding subpixel, namely the red subpixel R, the green subpixel G, or the blue subpixel B, of the pixel unit 23. Accordingly, when the NMOS turns on, the drive unit 10 outputs the gray level voltage OUT_{—}1˜OUT_M to the respective subpixel for driving each of the subpixel to correspondingly display a gray level.

The resistor string unit 11 and the digital-to-analog conversion unit 13 constitute a digital-to-analog converter (DAC). The resistor string unit 11 may be a resistor string or an R2R resistor ladder. The digital-to-analog conversion unit 13 may be a decoding circuit formed by an array of switches. The digital-to-analog conversion unit 13 drives the resistor string unit 11 to provide an output voltage by controlling the built-in array of switches according to a digital signal received.

More specifically, the control unit 15 can generate the digital signal for driving the pixel unit 23 according to the image data. The control unit 15 also drives the digital-to-analog conversion unit 13 to control the built-in array of switch and decode the digital signal. Subsequently, a data signal DATA_IN is outputted to a buffer unit 170 of the output unit 17 to correspondingly drive the subpixels of the pixel unit 23. It should be appreciated that the circuit architecture and the operation of the resistor string unit 11 and the digital-to-analog conversion unit 13 are well known to those skilled in the art and further descriptions are hereby omitted.

The output unit 17 includes a plurality of buffer units 170. The number of the buffer units 170 depends upon the number of the switch units 21 employed on the organic light emitting display panel 20. The buffer units 170 simultaneously transform the data signals DATA_IN, which are generated by the digital-to-analog conversion unit 13, to the gray level voltages OUT_{—}1˜OUT_M. The gray level voltages OUT_{—}1˜OUT_M are then outputted by the buffer units 170 to the organic light emitting display panel 20 for driving the pixel unit 23 to display the gray level corresponding to the image data so as to generate an image.

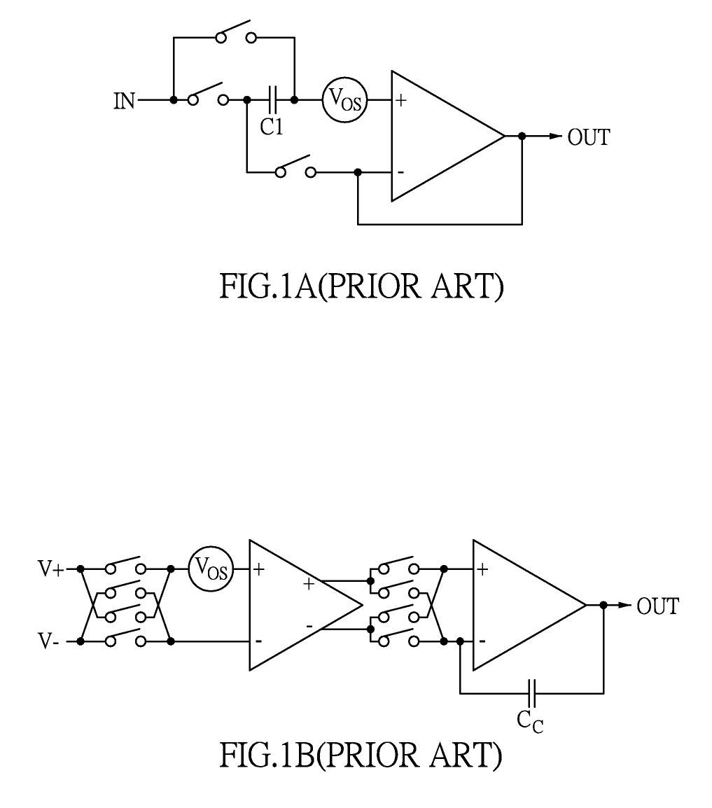

Each of the buffer units 170 includes a calibration unit 171 and a buffer circuit 173. The calibration unit 171 is coupled between the control unit 15 and the buffer circuit 173. The buffer circuit 173 is coupled between the digital-to-analog conversion unit 13 and the switch units 21, and the buffer circuit 173 is controlled by the control unit 15. The buffer circuit 173 is formed by an operational amplifier (not shown in FIG. 1) and a plurality of switches. The calibration unit 171 calibrates the output offset voltage V_OFFSET of the operational amplifier according to the output voltage of the operational amplifier of the buffer circuit 173.

In the instant embodiment, each driving cycle executed by the drive circuit 10 includes at least one driving period and at least one calibration period. In more detail, the control unit 15 inserts at least one calibration period in a driving cycle while the drive circuit 10 is under operation.

For example, in one driving cycle, given the driving method of the organic light emitting display 1 is by respectively driving the red subpixel R, the green subpixel G, and the blue subpixel B of the pixel units 23 in succession to show corresponding gray level. The driving cycle therefore includes three driving periods. In addition, the control unit 15 can insert the calibration period before or after the three driving periods, or in between any two adjacent driving periods.

Alternatively, in one driving cycle, given the driving method of the organic light emitting display 1 is by driving the red subpixel R, the green subpixel G and the blue subpixel B of the pixel units 23 in succession. The driving cycle may include a driving period and at least one calibration period. The control unit 15 can insert the calibration period before or after the driving period. The control unit 15 can also respectively insert the calibration period both before and after the driving period depend upon operating requirements. For example, calibration may be performed during black frame insertion for eliminating motion blur. As a result, in the buffer circuit 173, the output offset voltage V_OFFSET, which is generated by the operational amplifier due to operational factors (such as the voltage switching or variations in the ambient temperature), is instantly calibrated.

The control unit 15 can insert the calibration period before or after any driving period or in between two adjacent driving periods. In this regard, calibration to the operational amplifier of the buffer circuit 173 can be conducted at any time according to the operational needs. Such that the display quality of the organic light emitting display 1 can be enhanced as each of the operational amplifier can accurately output the gray level voltage driving the pixel units 23 of the organic light emitting display panel 20 during the driving period of each driving cycle.

In short, during calibration period the control unit 15 enables each calibration unit 171 of the output unit 17 and the corresponding buffer circuit 173 to proceed with the calibration procedure simultaneously. More specifically, the control unit 15 simultaneously outputs a clock signal CK and a counting signal CNT to each calibration unit 171 and a calibration control signal OZCD to each buffer circuit 173, such that the calibration unit 171 and the buffer circuit 173 undergo the calibration procedure. During the execution of the calibration procedure, each of the calibration units 171 continuously detects change in the output voltage of the operational amplifier (not shown in FIG. 1) of the corresponding buffer circuit 173. The calibration unit 171 calibrates the output offset voltage V_OFFSET generated by the operational amplifier of the buffer circuit 173 according to the detection results.

The control unit 15 respectively outputs the clock signals CK_R, CK_G and CK_B during the driving period. The clock signals sequentially switch the red pixel switch 211, the green pixel switch 213, and the blue pixel switch 215 on the organic light emitting display panel 20. In addition, the control unit 15 operatively drives the digital-to-analog conversion unit 13 to output the data signal DATA_IN to the corresponding buffer circuit 173 according to the image data. Subsequently, each buffer circuit 173 outputs the gray level voltages OUT_{—}1˜OUT_M to the organic light emitting display panel 20 according to the data signal DATA_IN received. The gray level voltages OUT_{—}1˜OUT_M then drives corresponding color subpixels of each pixel unit 23 on the organic light emitting display panel 20 displaying the gray level corresponding to the image data.

Accordingly, the instant disclosure can effectively eliminate the effect of the gray level voltage OUT_{—}1˜OUT_M during the driving period as the operational amplifier can automatically detect and calibrate the output offset voltage V_OFFSET, and the bias voltage of the gray level voltage is controlled between +/−0.25 LSB. In which, the +/−0.25 LSB can be derived from dividing the operational voltage range of the gray level voltage by the total grey levels of the gray level voltage (i.e., 2̂k, where k is a positive integer).

For example, when the operational voltage range of the gray level voltage ranges from 0 volt(V) to 5 volt(V), and the gray level voltage is represented by 12-bit. Using the calibration technique disclosed by the instant disclosure, the bias voltage of the gray level voltage can be operatively controlled to fall between +/−0.25*(5V/2̂12) or +/−0.25 mV.

The instant disclosure provides a low-power based calibration technique. The calibration technique can instantly calibrate the output offset voltage V_OFFSET of the operational amplifier. Thereby, the efficiency of the drive circuit 10 can be increased, while the display quality of the organic light emitting display panel 20 can be improved as well.

It should be noted that the output offset voltage V_OFFSET of the operational amplifier in each buffer circuit 173 of the output unit 17 may vary because of the operational factors (such as the operating voltage, the ambient temperature and the like) varies for different operational amplifier. Therefore, the calibration time of the operational amplifier in each buffer circuit 173 may vary. Accordingly, the calibration period inserted by the control unit 15 may be a maximum calibration time for a single operational amplifier. For example, the calibration period can be configured according to a calibration time for the maximum output offset voltage V_OFFSET. Accordingly, the operational amplifier of each buffer circuit 173 can complete the calibration of the output offset voltage V_OFFSET during the given calibration period.

In practice, the drive circuit 10 may be implemented by a drive chip. The control unit 15 may be implemented by a processing chip including but not limited to a microcontroller, or an embedded controller, which is programmed with necessary firmware design. The control unit 15 may be also integrated in the drive chip, however the instant disclosure is not limited thereto. The driving period and calibration period of the driving cycle can be predefined in the memory of the control unit 15 through firmware.

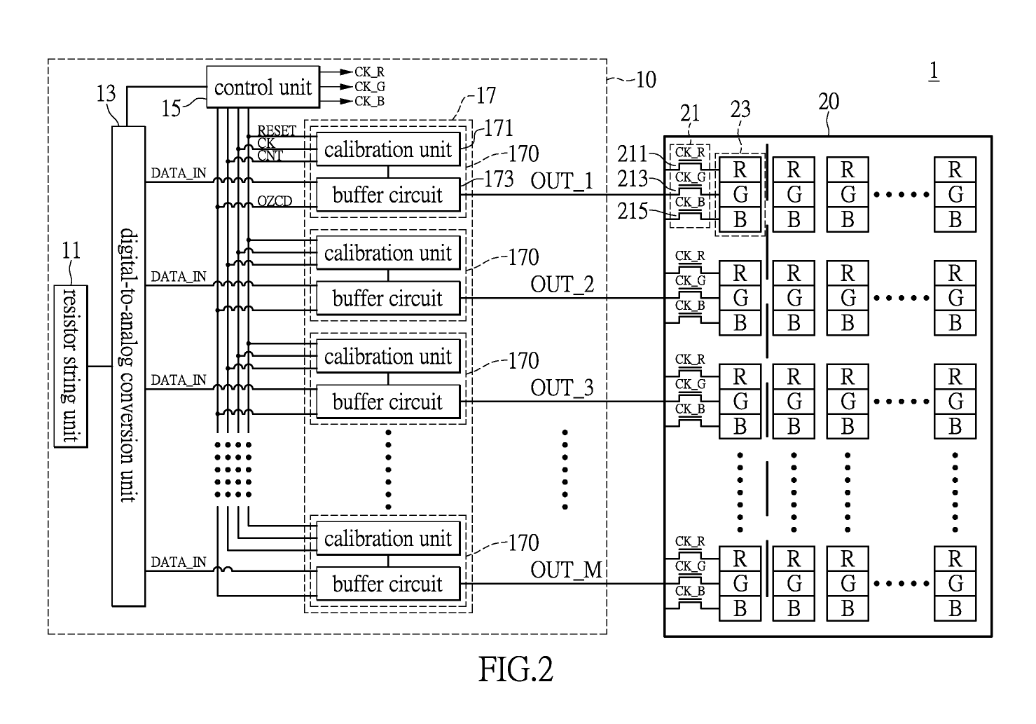

Hereinafter the detailed circuit architecture and the operation of a buffer unit 170 are elaborated. Please refer to FIG. 3 in conjunction to FIG. 2. FIG. 3 shows the circuit layout of the buffer unit in accordance with an embodiment of the instant disclosure.

As mentioned above, each of the buffer unit 170 includes the calibration unit 171 and the buffer circuit 173. The calibration unit 171 further includes a detection unit 1711 and a latch control circuit 1713. The buffer circuit 173 further includes an operational amplifier OA, a first switch SW1, a second switch SW2, and a third switch SW3. The operational amplifier OA also includes a non-inverting input terminal, an inverting input terminal, an output terminal, a plurality of control terminals, and a latch terminal.

Specifically, the detection unit 1711 is coupled to the latch control circuit 1713 and the output terminal of the operational amplifier OA to detect the output voltage CMP outputted by the operational amplifier. The latch control circuit 1713 is coupled to the control unit 15 and the latch terminal of the operational amplifier OA. The latch control circuit 1713 operatively outputs the latch signal L̅T̅H̅ to the latch terminal of the operational amplifier OA according to the counting signal CNT and the detection result of the detection unit 1711 to calibrate the output offset voltage V_OFFSET of the operational amplifier OA.

The non-inverting input terminal of the operational amplifier OA is coupled to the output of the digital-to-analog conversion unit 13 to receive a data signal DATA_IN. A first end of the first switch SW1 is coupled to the non-inverting input terminal of the operational amplifier OA, while a second end of the first switch SW1 is coupled to the inverting input terminal of the operational amplifier OA. In other words, the inverting input terminal of the operational amplifier OA is coupled to the non-inverting input terminal of the operational amplifier OA through the first switch SW1.

The control terminals of the operational amplifier OA are coupled to the calibration unit 171 for receiving a plurality of control signals CTRL_{—}1˜CTRL_Y outputted by the calibration unit 171, in which Y is a positive integer. In more detail, the control terminals of the operational amplifier OA are connected to the calibration unit 171 through a plurality of transmission buses for receiving the control signals CTRL_{—}1˜CTRL_Y.

The second switch SW2 is coupled between the inverting input terminal of the operational amplifier OA and the output terminal of the operational amplifier OA. A first end of the second switch SW2 is coupled to the inverting input terminal of the operational amplifier OA, while a second end of the second switch SW2 is coupled to the output terminal of the operational amplifier OA. The third switch SW3 is coupled between the output terminal of the operational amplifier OA and the respective switch unit 21 of the organic light emitting display panel 20. More specifically, a first end of the third switch SW3 is coupled to the output terminal of the operational amplifier OA, while a second end of the third switch SW3 is coupled to the red pixel switch 211, the green pixel switch 213, and the blue pixel switch 215 respectively.

In the instant embodiment, the first switch SW1, the second switch SW2, and the third switch SW3 switch simultaneously. Specifically, during the driving period, the control unit 15 operatively outputs a calibration control signal OZCD simultaneously turns on the second switch SW2 and the third switch SW3, while turns off the first switch SW1. The operational amplifier OA, the first switch SW1, the second switch SW2, and the third switch SW3 then form the buffer circuit. During the driving period, the operational amplifier OA outputs the gray level voltage OUT_X (i.e., one of the gray level voltages OUT_{—}1˜OUT_M) to the corresponding subpixel of the pixel units 23 of the organic light emitting display panel 20 according to the data signal DATA_IN received by the non-inverting input terminal. The pixel units 23 of the OLED display panel 20 is therefore driven and displays the corresponding gray level of the image data to generate an image.

During calibration period, the control unit 15 operatively outputs the calibrating the calibration control signal OZCD and turns on the first switch SW1 while turns off the second switch SW2 and the third switch SW3. The operational amplifier OA and the first switch SW1 collectively form a comparison circuit. The detection unit 1711 of the calibration unit 171 detects the output voltage CMP of the operational amplifier OA. Additionally, the latch control circuit 1713 of the calibration unit 171 adjusts the bias current of the operational amplifier OA according to the output voltage CMP of the operational amplifier OA so as to calibrate the output offset voltage V_OFFSET of the operational amplifier OA.

At the same time, since the third switch SW3 is turned off, the connection between the buffer unit 170 and the organic light emitting display panel 20 is therefore cut off. Hence, the output of operational amplifier OA at this time does not affect the operation of the organic light emitting display panel 20.

Specifically, the control unit 15 outputs a reset signal RESET (e.g., a reset signal RESET of high voltage level) when entering the calibration period. As a result, the latch control circuit 1713 is reset. Meanwhile, the control unit 15 outputs the calibration control signal OZCD to form the comparison circuit between the operational amplifier OA and the first switch SW1. Subsequently, when the control unit 15 outputs the clock signal CK, the latch control circuit 1713 proceeds with the calibration procedure.

In the calibration procedure, the calibration unit 171 gradually adjusts the bias current generated by the internal bias circuit of the operational amplifier OA according to the counting signal CNT. The calibration unit 171 calibrates the output offset voltage V_OFFSET of the operational amplifier OA to approximately zero voltage level. The latch control circuit 1713 determines whether to stop the calibration procedure according to the detection result of the output voltage CMP of the operational amplifier OA from the detection unit 1711. That is to say, the latch control circuit 1713 determines whether the output offset voltage V_OFFSET has been calibrated to approximately zero voltage level.

When the detection unit 1711 detects a logic level change in the output voltage CMP of the operational amplifier OA (e.g., a change from a high voltage level to low voltage level or vice versa), the latch control circuit 1713 outputs the latch signal L̅T̅H̅ to the latch terminal of the operational amplifier OA. The calibration procedure is then terminated, and the operational amplifier OA internal bias circuit maintains the existing bias current. The latch control circuit 1713 calibrates the output offset voltage V_OFFSET thereby.

In other words, as long as the detection unit 1711 detects a logic level change in the output voltage CMP of the operational amplifier OA, which refers to that zero-crossing phenomenon, the output offset voltage V_OFFSET is determined to be calibrated to approximately zero voltage level.

In the instant embodiment, the first switch SW1, the second switch SW2, and the third switch SW3 enables the operational amplifier OA to switch to the comparison circuit or the buffer circuit. In compared to the conventional technique (as shown in FIG. 1C), additional comparison circuits can be removed. That is Unnecessary circuit can be removed thereby reduce the circuitry area required for the driving circuit. Meanwhile, the instant disclosure can also eliminate the errors of the bias voltage generated by the additional comparison circuit, hence the calibration accuracy can be therefore increased.

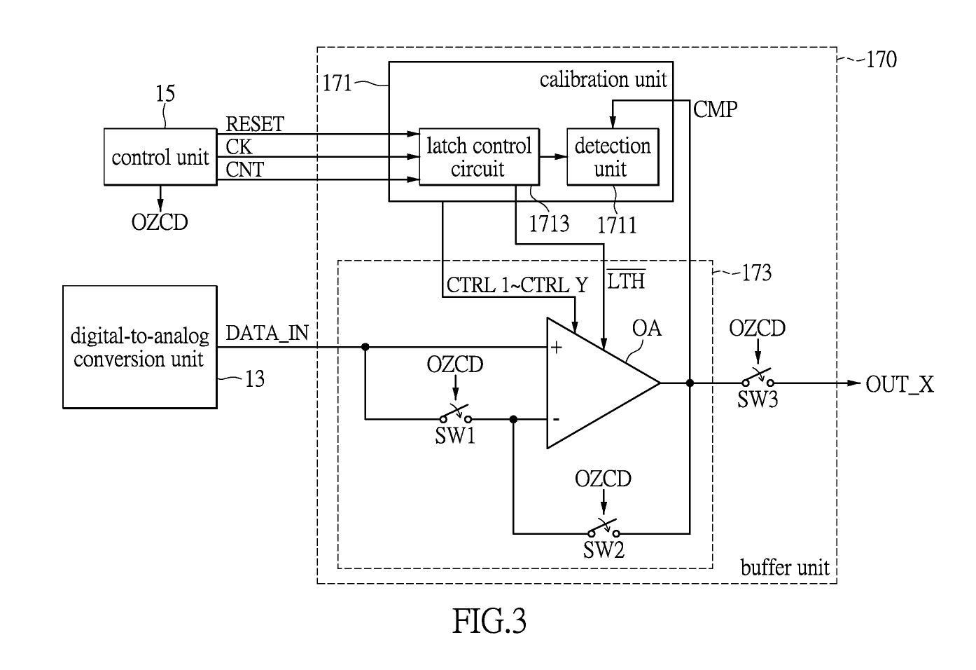

Hereinafter describes the overall operation of the drive circuit 10 of the organic light emitting display 1 in detail. Please refer to FIG. 4 in conjunction to FIG. 2 and FIG. 3. FIG. 4 shows a diagram illustrating an operation of the drive circuit of the organic light emitting display in accordance with an embodiment of the instant disclosure.

Between time points T1 to T4 (i.e., the driving period), the control unit 15 outputs the calibration control signal OZCD of the low voltage level. Each buffer circuit 173 of the output unit 17 generates the corresponding gray level voltage OUT_X (i.e., one of the gray level voltages OUT_{—}1˜OUT_M) according to the data signal DATA_IN outputted by the digital-to-analog conversion unit 13. Meanwhile, the control unit 15 outputs the clock signals CK_R, CK_G and CK_B in sequence to enable the red pixel switch 211, the green pixel switch 213, and the blue pixel switch 215 of the corresponding switch unit 21 on the OLED display panel 20. The gray level voltage OUT_X (i.e., one of the gray level voltages OUT_{—}1˜OUT_M) is then transmitted to the corresponding pixel unit 23 of the organic light emitting display panel 20.

In more detail, between time points T1 to T2, the control unit 15 transmits the clock signals CK_R to enable the red pixel switches 211. The gray level voltage OUT_X (i.e., one of gray level voltages OUT_{—}1˜OUT_M) outputted by the operational amplifier OA of the buffer circuit 173 of the output unit 17 drives each respective red subpixel R of the organic light emitting display panel 20 through the red pixel switches 211. Between time points T2 to T3, the control unit 15 transmits the clock signals CK_G to enable the green pixel switches 213. The gray level voltage OUT_X (i.e., one of the gray level voltages OUT_{—}1˜OUT_M) outputted by the operational amplifier OA of the buffer circuit 173 of the output unit 17, drives each respective green subpixel R of the organic light emitting display panel 20 through the green pixel switches 213. The control unit 15 further transmits the clock signals CK_B to enable the blue pixel switch 215 between time points T3 to T4. The gray level voltage OUT_X, which is outputted by the operational amplifier OA of the buffer circuit 173 of the output unit 17 drive each respective blue subpixel B of the organic light emitting display panel 20 through the blue pixel switches 215.

It should be noted that, the detection unit 1711 of the calibration unit 171 detects the delayed gray level voltages output by the operational amplifier OA.

Between time points T4 to T7 (i.e., the calibration period), the control unit 15 outputs the calibration control signal OZCD having high voltage level. The buffer circuits 173 of the output unit 17 are transformed into the comparison circuit. The comparison circuit then compares the voltages from the non-inverting and the inverting input terminals of the operational amplifier OA to generate the corresponding output voltage CMP. Since the first switch SW1 is turned on causing the input voltages of the non-inverting and inverting input terminals of the operational amplifier OA to be equal to each other. As a result, the output offset voltage V_OFFSET of the operational amplifier OA can be detected through the output voltage of the operational amplifier OA.

Meanwhile, because the connection between the operational amplifier OA and the switch unit 21 of the organic light emitting display panel 20 is cut off. The gray level voltage OUT_X received by the switching unit 21 is the voltage before entering the calibration period. However, in other embodiments, the gray level voltage OUT_X received by the switching unit 21 may be a preset voltage by a circuit (e.g., pull up to the supply voltage or pull down to the ground), and the instant disclosure is not limited thereto. Then, the control unit 15 outputs the clock signal CK to operatively drive the latch control circuit 1713 of the calibration unit 171 to enter the calibration procedure.

Between time points T4 to T6, the control unit 15 outputs the counting signal CNT cause the calibration unit 171 to correspondingly output the latch signal L̅T̅H̅ (e.g., a high voltage level signal) and the control signals CTRL_{—}1˜CTRL_Y. In this regard, the calibration unit 171 gradually adjusts the bias current generated by the internal bias circuit of the operational amplifier OA. When the detection unit 1711 detects a logic level change (e.g., from a low voltage level to a high voltage level) in the output voltage CMP of the operational amplifier OA, indicating zero crossing has occurred. More specifically, when the output offset voltage V_OFFSET of the operational amplifier OA crosses the zero point (i.e., time point T5), the latch control circuit 1713 immediately outputs the latch signal L̅T̅H̅ (e.g., a low voltage level signal) to the latch terminal of the operational amplifier OA as shown at the time point T6 to terminated the calibration procedure. The bias current of generated by the internal bias circuit of the operational amplifier OA is maintained so as to calibrate the output offset voltage V_OFFSET

Subsequently, at the time point T7, the control unit 15 initiates the driving period again. The control unit 15 operatively drives the pixel units 23 of the organic light emitting display panel 20 according to the image data. The operation of the drive circuit 10 is the same as the driving period from time points T1 and T4, and further descriptions are hereby omitted.

It is worth to note that the output offset voltages V_OFFSET of the operational amplifier OA of each buffer circuit 173 may be different. Therefore, each operational amplifier OA may require different calibration periods (i.e., from time point T4 to time point T6). The calibration period may be predefined according to a maximum calibration period required by an operational amplifier OA or an average calibration period of each operational amplifier OA. The calibration period may be predefined in the memory of the control unit 15, however the instant disclosure is not limited thereto. FIG. 4 merely shows a circuit operation of the drive circuit of an organic light emitting display and a calibration method for the operational amplifier OA but the instant disclosure is not limited thereto.

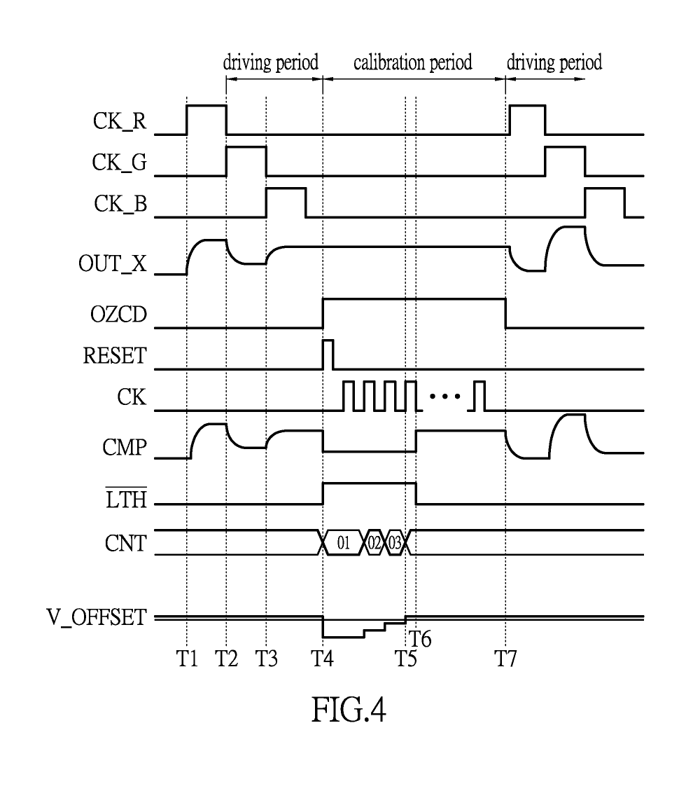

In order to further understand the calibration technology of the operational amplifier OA in accordance with an embodiment of the instant disclosure, the detailed circuitry and calibration method for the operational amplifier OA are further described hereinafter. Please refer to FIG. 5. FIG. 5 is a detailed schematic diagram illustrating an operational amplifier in accordance with an embodiment of the instant disclosure.

In the instant embodiment, the operational amplifier OA is a differential folded cascade CMOS operational amplifier. Specifically, the operational amplifier OA has a differential input stage 1731, a bias stage 1733, an offset voltage adjustment unit 1735, and an output stage 1737. The differential input stage 1731 is coupled to the bias stage 1733. The bias stage 1733 is coupled between the power terminal VDD and the offset voltage adjustment unit 1735. The offset voltage adjustment unit 1735 is coupled between the bias stage 1733 and the ground GND. The output stage 1737 is coupled to the bias stage 1733.

The bias stage 1733 is a symmetrical folded cascade bias stage. Furthermore, the circuit of the bias stage 1733 and the offset voltage adjustment unit 1735 collectively form the bias circuit of the operational amplifier OA. The bias stage 1733 is configured to generate a bias current for adjusting the output offset voltage V_OFFSET of the operational amplifier OA.

The circuitry of the operational amplifier OA and the operation thereof are well known to those skilled in the art. However, the internal circuitry of the operational amplifier OA is briefly described hereinafter to provide a complete picture for the calibration procedure disclosed by the instant disclosure.

The differential input stage 1731 includes an n-type differential pair 17311 and a p-type differential pair 17313. The n-type differential pair 17311 is coupled to the p-type differential pair 17313. The common-mode voltage of the operational amplifier OA ranges from 0 volt to the input voltage of the power terminal VDD. The n-type differential pair 17311 is a common source configuration comprised of the NMOS transistors MN1 and MN2. The sources of the NMOS transistors MN1, MN2 are connected to the power terminal VDD together through a current source CS1. The p-type differential pair 17313 is a common source configuration comprised of the PMOS transistors MP1 and MP2. The sources of the PMOS transistors MP1, MP2 are connected to the ground GND together through a current source CS2. The current source CS1 is configured to provide a constant bias current to the NMOS transistors MN1, MN2, while the current source CS2 provides a constant bias current to the PMOS transistors MP1, MP2.

The NMOS transistor MN2 of the n-type differential pair 17311 and the PMOS transistor MP1 of the p-type differential pair 17313 respectively connect to the non-inverting input terminal V+ of the operational amplifier OA. The NMOS transistor MN1 of the n-type differential pair 17311 and the PMOS transistors MP2 of the p-type differential pair 17313 respectively connect to the inverting input terminal V− of the operational amplifier OA. The drains of the NMOS transistors MN1, MN2 are coupled to the drains of the NMOS transistors MN5 and MN6 of the bias stage 1733, respectively. The drains of the PMOS transistors MP1, MP2 are coupled to the drains of the PMOS transistors MP3 and MP4 of the bias stage 1733, respectively.

The bias stage 1733 is a symmetrical bias circuit. The bias stage 1733 can be further divided into a left-side bias circuit 17331 and a right-side bias circuit 17333. In addition, the bias stage 1733 includes a current mirror, a floating current source, a bias control circuit, an active load, a bias resistor R1, and a bias resistor R2. The current mirror is formed by the PMOS transistors MP3˜MP6. The floating current source is formed by the PMOS transistor MP7 and the NMOS transistor MN3. The bias control circuit is formed by the PMOS transistor MP8 and the NMOS transistor MN4. The active load is formed by the NMOS transistors MN5˜MN8. The floating current source drives the current mirror to generate the bias current. The NMOS transistors MN5, MN6 and the gates of the NMOS transistors MN7, MN8 adjust the equivalent resistance of the NMOS transistors MN5˜MN8 in the triode region according to the external offset voltages VBIAS 1 and VBIAS2 inputted. The external offset voltages VBIAS3 and VBIAS4 control the operations of the NMOS transistors MN7, MN8 and the PMOS transistors MP7, MP8.

The bias resistor R1 is coupled between the NMOS transistor MN7 and the offset voltage adjustment unit 1735. The bias resistor R2 is coupled between the NMOS transistor MN8 and the offset voltage adjustment unit 1735. The bias resistor R1 adjusts the bias current Ia generated by the left-side bias circuit 17331, while the bias resistor R2 adjusts the bias current Ib generated by the right-side bias circuit 17333. The bias current Ia and Ib control the driving voltage outputted to the output stage 1737 from the junctions Va, Vb.

The output stage 1737 is a rail to rail output stage. The output stage 1737 includes the PMOS transistor MP9 and the NMOS transistor MN9. The gate of the PMOS transistor MP9 is coupled to the junction Va, and the gate of the NMOS transistors MN9 is coupled to the junction Vb. The drain of the PMOS transistors MP9 is coupled to the power supply terminal VDD. The drain of the NMOS transistors MN9 is coupled to the ground GND. The sources of the PMOS transistor MP9 and the NMOS transistor MN9 are collectively coupled to the output terminal of the operational amplifier OA. The sources of the PMOS transistor MP9 and the NMOS transistor MN9 generate an output voltage (i.e., the output voltage CMP or the gray level voltage OUT_X) according to the driving voltage outputted by the bias stage 1733 at the junctions Va, Vb.

The output stage 1737 further includes a frequency compensation circuit. The frequency compensation circuit comprise of switches SW4, SW5 and miller capacitors Cc1, Cc2. The frequency compensation circuit compensates the frequency response of the operational amplifier OA by means of miller effect. Specifically, the frequency compensation circuit adjusts the zero positions of the operational amplifier OA through the miller capacitor Cc1, Cc2. The frequency compensation circuit adjusts the operating bandwidth of the operational amplifier OA to prevent operation of the operational amplifier OA from become unstable under high frequency. Meanwhile, the miller capacitor Cc1, Cc2 can also use to prevent excessive current from damaging the PMOS transistor MP9 and the NMOS transistor MN9.

The control unit 15 is configured to turn on the switches SW4, SW5 for frequency compensation during the driving period. The operational amplifier OA does not need to conduct frequency compensation during the calibration period, so the control unit 15 is configured to turn off the switches SW4, SW5.

The offset voltage adjustment unit 1735 is configured to adjust the equivalent resistance between the left-side bias circuit 17331 and the ground GND bias current (i.e., the left-side bias resistance) and the equivalent resistance between the right-side bias circuit 17333 and the ground GND (i.e., the right-side bias resistance). In this regard, the bias current Ia, Ib is gradually adjusted, and the output offset voltage V_OFFSET of the operational amplifier OA is calibrated thereby.

In more detail, the offset voltage adjustment unit 1735 includes a resistor string 17351 and a plurality of latch units 17353. The latch units 17353 are coupled to the resistor string 17351. The resistor string 17351 has a first end A and a second end B. The first end A and the second end B of the resistor string 17351 are coupled to the bias stage 1733, respectively. The first end A of the resistor string 17351 is coupled to the bias resistor R1, while the second end B of the resistor string 17351 is coupled to the bias resistor R2.

A plurality of resistors Rc (e.g., z resistors, wherein z is an integer) is in connected in series between the first end A and the second end B of the resistor string 17351 forming a plurality of junctions Vc. The latch units 17353 are coupled between the junction Vc and the ground GND. That is to say, each latch unit 17353 is coupled between the junction Vc of any two adjacent resistors Rc and the ground GND.

The calibration unit 171 sequentially conducts one of the latch units 17353 (e.g., the ith latch unit) of the offset voltage adjustment unit 1735. In other words, the calibration unit 171 conducts the junction Vc connected to the latch units 17353 and the ground GND for adjusting the left-side bias resistance (i.e., the equivalent resistance between the left-side bias circuit 17331 and the ground GND) and the right-side bias resistance (i.e., the equivalent resistance between the right-side bias circuit 17333 and the ground GND) so as to adjust the bias current Ia, Ib. To put it concretely, the calibration unit 171 can adjust the driving voltages of the gate of the PMOS transistor MP9 and the NMOS transistors MN9 through adjusting the bias current Ia, Ib.

Please refer to FIG. 5 again in conjunction with FIGS. 3 and 4. When the control unit 15 enables the calibration unit 171 to perform the calibration procedure during the calibration period, the control unit 15 outputs the counting signal CNT causes the calibration unit 171 to sequentially output the control signals CTRL_{—}1˜CTRL_Y. The control signals CTRL_{—}1˜CTRL_Y conduct one of the latch units in sequence, (e.g., start conduct the leftmost latch unit 17353 of the bias circuit 17331 or the rightmost latch unit 17353 of the bias circuit 17333), to gradually adjust (e.g., increase or decrease) the left-side bias resistance and the right-side bias resistance. When the left-side bias resistance increases, the right-side bias resistance correspondingly decreases; when the left-side bias resistance decreases, the right-side bias resistance correspondingly increases.

Accordingly, the calibration unit 171 adjusts (increases or decreases) the left-side bias resistance and the right-side bias resistance by using the offset voltage adjustment unit 1735 for gradually adjusting the bias current Ia, Ib so that the output offset voltage V_OFFSET of the operational amplifier OA approaches zero voltage level.

When the detection unit 1711 of the calibration unit 171 detects that the output voltage CMP (i.e., the source voltages of the PMOS transistor MP9 and the NMOS transistor MN9) outputted by the operational amplifier OA changes from a high voltage level to a low voltage level or from a low voltage level to a high voltage level, the latch control circuit 1713 of the calibration unit 171 outputs the latch signal L̅T̅H̅ (e.g., a low voltage level signal) to stop the calibration procedure and drive the latch units 17353 to enter a latch state. The output offset voltage V_OFFSET of the operational amplifier OA is then calibrated. In the latch state, only one of the latch units 17353 is conducted, while the other latch units 17353 are turned off.

That is to say, during the calibration procedure, the calibration unit 171 conducts one of the latch units 17353 according to the detection results of the detection unit until the output voltage CMP of the operational amplifier OA undergoes a logic level change. After the completion of the calibration procedure, the latch control circuit 1713 of the calibration unit 171 outputs the latch signal L̅T̅H̅ causing the latch units 17353 to enter the latch state, such that only one of the latch units 17353 selected remains conducted so as to adjust the output offset voltage V_OFFSET of the operational amplifier OA.

For example, when the calibration unit 171 conducts the fourth latch unit 17353 starting from the bias resistors R1, according to the counting signal CNT during the calibration procedure, the detection unit 1711 detects that the output voltage CMP of the operational amplifier OA undergoes a logic level change. The latch control circuit 1713 operatively outputs the latch signal L̅T̅H̅ and terminates the calibration procedure causing the latch units 17353 to enter the latch state. The fourth latch unit 17353 remains conducted, while the other latch units 17353 are turned off until the next calibration period.

In this case, the left-side bias resistance is the resistance of the bias resistor R1+4* the resistance of resistor Rc, and the right-side bias resistance is the resistance of the bias resistance R2+(z−4)* the resistance of the resistor Rc.

It is worth to note that the bias resistors R1, R2 can be configured according to the actual operational requirement of the operational amplifier OA (e.g., the operational requirements of the bias stage 1733). The actual resistance of the resistor Rc may be configured according to the actual calibration requirements of the output offset voltage V_OFFSET in each stage. The number of resistor Rc may vary according to the calibration magnitude of the output offset voltage V_OFFSET at each calibration step required. The instant disclosure is not limited thereto.

In the instant embodiment, the counting signal CNT may be a binary signal. The number of bits of the binary signal can be configured according to the number of the latch units 17353 used. For example, ^{┌}┌log₂(z−1)┐_{┘}, where z refers to the number of resistors in the resistor string 17353.

The calibration unit 171 may also include a multiplexing unit (not shown). The multiplexing unit can generate a plurality of control signals CTRL_{—}1˜CTRL_Y controlling the operations of the latch units 17353 according to the counting signal CNT. The number of the control signals CTRL_{—}1˜CTRL_Y and the number of the control terminals of the operational amplifier OA may depend on the number of the latch units 17353. The multiplexing unit may be implemented by single input and multiple outputs multiplexer.

The control unit 15 operatively outputs the counting signal CNT during calibration period driving the multiplexing unit of the calibration unit 171 of each buffer unit 17 to sequentially conduct one of the respective latch units 17353 to adjust the bias current of the operational amplifier OA. Such that the output offset voltage V_OFFSET of the operational amplifier OA is calibrated. When the counting signal CNT finish conducting all of the latch units 17353 of the operational amplifier OA (i.e., when the counting signal CNT reaches the maximum) or when the output voltage of the operational amplifier OA undergoes a logic level change, the calibration unit 171 outputs the latch signal causing the latch units 17353 to enter the latch state and terminates the calibration procedure.

Incidentally, in another embodiment, the control unit 15 may output a clock signal imitating the calibration unit 171 to generate the control signals CTRL_{—}1˜CTRL_Y. The control signals CTRL_{—}1˜CTRL_Y to sequentially conduct one of the latch units 17353 of the offset voltage adjustment unit 1735. In still another embodiment, the multiplexing unit may be built-in in the operational amplifier OA. The multiplexing unit operatively outputs the control signals CTRL_{—}1˜CTRL_Y according to the counting signal CNT received from the control unit 15 and conducts one of the latch units 17353 of the offset voltage adjustment unit 1735.

In short, the generation of the counting signal CNT and the control signals CTRL_{—}1˜CTRL_Y can be configured according to exact circuit design and/or operational requirements so long as the latch units 17353 of the offset voltage adjustment unit 1735 can be sequentially conducted, such that the bias current Ia, Ib generated by internal bias circuit of the operational amplifier OA can be adjusted and the output offset voltage V_OFFSET of the operational amplifier OA can be calibrated.

It should be noted that, FIG. 5 merely serve as a circuit illustration and the circuit architecture of the operational amplifier may vary according to actual operational requirement. For example, the bias compensation method for the differential input stage 1731, the circuitry of the bias voltage circuit or the types of the output stage may be different according to actual operational requirement. In other words, FIG. 5 merely used to describe circuitry of the offset voltage adjustment unit 1735 when applied in the operational amplifier OA, and the instant disclosure is not limited thereto.

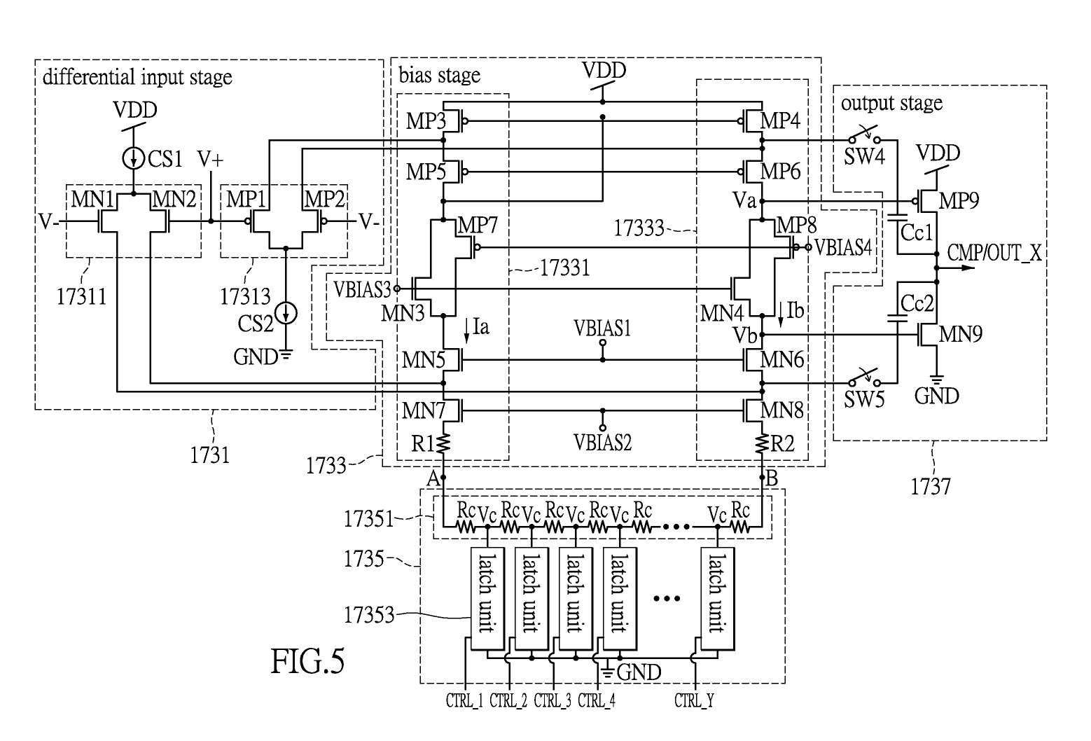

The instant disclosure further provides another embodiment regarding the latch unit 17353. Please refer to FIG. 6 in conjunction with FIGS. 3 and 5. FIG. 6 shows a schematic diagram illustrating the latch unit in accordance with an embodiment of the instant disclosure. Each latch unit 17353 includes an NMOS transistor MN10, an NMOS transistor MN11, and a storage capacitor Cgs.

The source of the NMOS transistor MN10 is coupled to the calibration unit 171 to receive a control signal CTRL_i (i.e., one of the control signals CTRL_{—}1˜CTRL_Y). A gate of the NMOS transistor MN10 is controlled by the calibration unit 171 to receive the latch signal L̅T̅H̅. A drain of the NMOS transistor MN10 is coupled to a gate of the NMOS transistor MN11. A drain of the NMOS transistor MN11 is coupled to the junction Vc formed between the resistor Rc. A source of the NMOS transistor MN11 is coupled to the ground GND. A first end of the storage capacitor Cgs is coupled to the junction between the drain of the NMOS transistor MN10 and the gate of the NMOS transistor MN10. A second end of the storage capacitor Cgs is coupled to the ground GND. The storage capacitor Cgs is coupled between the gate of the NMOS transistor MN11 and the source of the NMOS transistor MN11.

When the control unit 15 enables the calibration unit 171 to enter the calibration procedure, the latch control circuit 1713 of the calibration unit 171 outputs the latch signal L̅T̅H̅ of a high voltage level to the gate of the NMOS transistor MN10. The multiplexing unit (not shown) of the calibration unit 171 subsequently conducts one of the NMOS transistor MN10 of the latch units 17353 according to the control signals CTRL_{—}1˜CTRL_Y outputted by the counting signal CNT to the source of the NMOS transistor MN10 of the latch units 17353. Meanwhile, when the NMOS transistor MN10 of the latch units 17353 is conducted, the storage capacitor Cgs of the latch unit 17353 is charged to maintain the NMOS transistor MN11 in conduction for a period (e.g., the discharge time of the storage capacitor Cgs). In other words, when the storage capacitor Cgs is fully charged, the NMOS transistor MN11 is still conducts until the storage capacitor Cgs is completely discharged. When the control signal CTRL_i (i.e., one of the control signals CTRL_{—}1˜CTRL_Y) received by the source of the NMOS transistor MN10 is of a low voltage level, the calibration unit 171 stops charging the storage capacitor Cgs. The NMOS transistors MN11 further turns off after the storage capacitor Cgs is completely discharged.

When the detection unit 1711 of the calibration unit 171 detects that the output voltage CMP of the operational amplifier OA undergoes a logic level change (e.g., from a high voltage level to a low voltage level or a low voltage level to a high voltage level), the latch control circuit 1713 of the calibration unit 171 outputs the latch signal L̅T̅H̅ to stop the operation of the NMOS transistor MN10 and causes the latch units 17353 to enter a latch state. That is to say, the NMOS transistor MN11 of one of the latch units 17353 selected remains conducted, while the other NMOS transistors MN11 of the latch units 17353 are turned off so as to calibrate the output offset voltage V_OFFSET of the operational amplifier OA. Additionally, the latch units 17353 remain in the latch state until the next calibration period.

It should be noted that, those skilled in the art should know how to choose the appropriate storage capacitor Cgs, such that the NMOS transistor MN11 of the selected latch unit 17353 remains conducted in the latch state so that the output offset voltage V_OFFSET of the operational amplifier OA is eliminated. Accordingly, during the driving period, the impact of the output offset voltage V_OFFSET of the operational amplifier OA on the display operation of the organic light emitting display panel can be effectively eliminated.

In addition, the instant embodiment discloses the latch units 17353 of the offset voltage adjustment unit 1735, which is incorporated with the NMOS transistor switching circuit. The conventional NMOS transistors can be minimized in the manufacturing process to reduce the area occupied by the circuit. Therefore, the instant embodiment can greatly reduce compensation circuit area of the output offset voltage of the operational amplifier OA by using NMOS transistor switching circuits. Furthermore, the circuitry of the latch unit 1735 utilizes a two-NMOS-transistor memory, which can retain the calibration setting for the compensation of the output offset voltage V_OFFSET. Accordingly, the area occupied by the drive circuit 10 can be effectively reduced, and the production cost thereof also decreases.

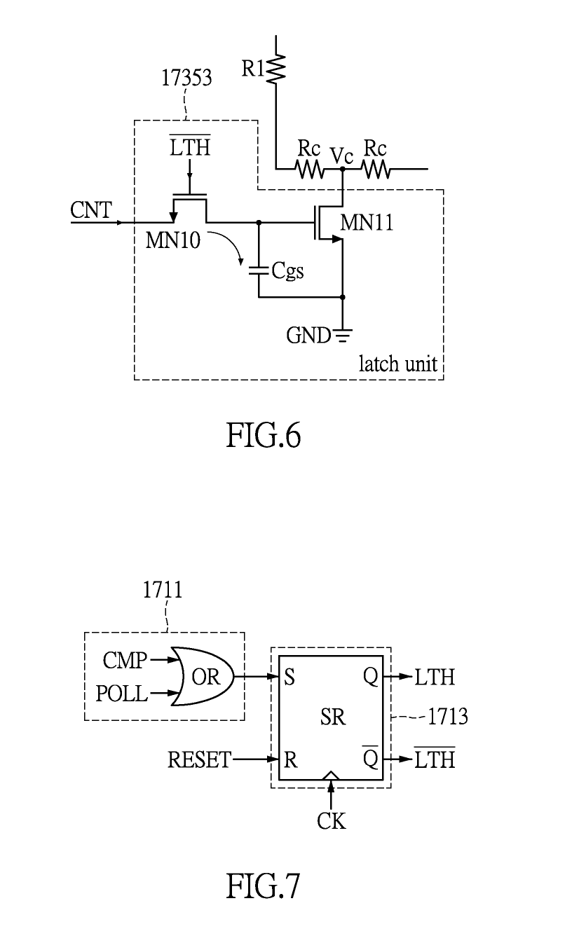

In addition, the implementation of the calibration unit 171 is provided in an embodiment of the instant disclosure. Please refer to FIG. 7 in conjunction with FIG. 3 and FIG. 5. FIG. 7 shows a circuit diagram illustrating the calibration unit in accordance with an embodiment of the instant disclosure. In the instant embodiment, the detection unit 1711 of the calibration unit 171 includes an or gate OR. The latch control circuit 1713 of the calibration unit 171 includes a SR flip-flop SR, and the SR flip-flop SR is a falling edge triggered flip-flop.

In more detail, a first input terminal of the or gate OR is coupled to the output terminal of the operational amplifier OA to receive the output voltage CMP of the operational amplifier OA. A second input terminal of the or gate OR is configured to receive a polling signal POLL. When the counting signal CNT has counted to the maximum (i.e., all of the latch units 17353 have been selected to conduct), the polling signal POLL is a high voltage level signal. Conversely, when the counting signal CNT has not counted to the maximum (i.e., some of the latch units 17353 have not been selected to conduct), the polling signal POLL is a low voltage level signal. The polling signal POLL can be directly outputted by the control unit 15 or generated by a determination circuit of the calibration unit 171 according to the counting signal CNT and the instant embodiment is not limited thereto.

The output terminal of the or gate OR is coupled to the input terminal S of the SR flip-flop SR. The input terminal R of the SR flip-flop SR is coupled to the control unit 15 to receive the reset signal RESET. The enable terminal CK of the SR flip-flop SR is coupled to the control unit 15 to receive the clock signal CK. The output terminal Q̅ of the SR flip-flop SR is coupled to the latch terminal of the operational amplifier OA to output the latch signal L̅T̅H̅ to the operational amplifier OA according to the detection results of the detection unit 1711.

When the control unit 15 enables the calibration unit 171 to proceed with the calibration period, the control unit 15 operatively outputs the reset signal RESET (e.g., an pulse signal) to the input terminal R of the SR flip-flop SR such that the SR flip-flop SR is reset. Then, the control unit 15 outputs the clock signal CK to enable the SR flip-flop SR. The SR flip-flop SR operatively generates the latch signal L̅T̅H̅ at the output terminal Q̅ according to the input signal of the input terminal S response to a falling edge of the clock signal CK.

In more detail, the control unit 15 outputs the counting signal CNT to sequentially conduct one of the latch units 17353 of the offset voltage adjustment unit 1735.

When the output voltage CMP of the operational amplifier OA is a low voltage level while the counting signal CNT has not reached the maximum counts, the first and the second input terminals of the or gate OR are both at low voltage levels. So that the output of the or gate OR turns out to be a low voltage level signal, and the output terminal Q̅ of the SR flip-flop SR correspondingly outputs a latch signal L̅T̅H̅ of high voltage level to the latch terminal of the operational amplifier OA. When either the output voltage CMP of the operational amplifier OA undergoes a logic level change or the counting signal CNT has counted to the maximum, the first input terminal or the second input terminal of the or gate OR is at high voltage level. Accordingly, the or-gate OR correspondingly outputs the high voltage level signal triggering the SR flip-flop SR. The output terminal Q̅ of the SR flip-flop SR correspondingly outputs the latch signal L̅T̅H̅ of low voltage level upon receiving the next falling edge of the clock signal CK causing the latch units 17353 to enter the latch state, in which only one of the latch units 17353 selected remains conducted. Accordingly, the output offset voltage V_OFFSET of the operational amplifier OA is calibrated.

It is worth to note that, in other implementation, the latch signal LTH (i.e., the inverted signal of the latch signal L̅T̅H̅) outputted by the terminal Q of the SR flip-flop SR can be configured to drive the latch units 17353 of the operational amplifier OA to enter the latch state. For example, the output terminal Q of the SR flip-flop SR can be coupled to the latch terminal of the operational amplifier OA through an inverter, or the latch terminal of the operational amplifier OA can be designed as an active-low trigger mode, such that the latch signal LTH outputted by the output terminal Q can be used to drive the latch units.

Specifically, if the NMOS transistor MN10 of the latch units 17353 of the operational amplifier OA is replaced by a PMOS transistor, the latch units 17353 can be controlled by the latch signal LTH outputted by the output terminal Q of the SR flip-flop SR. More specifically, the output terminal Q of the SR flip-flop SR of the calibration unit 171 thus can output the latch signal LTH in coordination with to the counting signal CNT controls the operations of the latch units 17353 according to the polling signal POLL and the output voltage CMP. When detected that the output voltage CMP of the operational amplifier OA undergoes a logic level change, or the counting signal CNT has counted to the maximum, the output terminal Q of the SR flip-flop SR correspondingly outputs the latch signal LTH of a high voltage level, which causes the latch units 17353 to enter the latch state. The actual implementation of how SR flip-flop SR driving the latch units 17353 can be designed based on actual operational requirement or the exact circuit design of the latch unit 17353. The instant embodiment does not intend to limit the scope of the instant disclosure.

The calibration unit 171 in practice can have other implementations. For example, the calibration unit 171 may be implemented by a comparator. A non-inverting input terminal of the comparator is configured to be coupled to the output terminal of the operational amplifier OA to receive the output voltage CMP. An inverting input terminal of the comparator is configured to be coupled to a reference voltage. The output terminal of the comparator is coupled to the latch terminal of the operational amplifier OA. Accordingly, the comparator can output the latch signal to stop the calibration procedure according to the output voltage CMP of the operational amplifier OA and the reference voltage. Therefore, the exact structure of the calibration unit 171 can be configured based on the calibration requirement. FIG. 7 is merely shows an implementation of the calibration unit, and the instant disclosure is not limited thereto.

In summary, the instant disclosure provides an offset voltage adjustment unit and a drive circuit of an organic light emitting display. The offset voltage adjusting unit can be applied for adjusting the output offset voltage of the operational amplifier, which is caused by the ambient temperature, the operating voltage, or process factors. The offset voltage adjusting unit can gradually adjust the bias current generated by bias circuit of the operational amplifier according to the output voltage of the operational amplifier. The offset voltage adjusting unit can accurately calibrate the output offset voltage generated by the operational amplifier. At the same time, the offset voltage adjustment unit can further record the calibration settings for the operational amplifier during the calibration process so as to stabilize the operation of the operational amplifier.

Accordingly, the offset voltage adjustment unit can be used to prevent the output offset voltage from affecting the driving operation of the organic light emitting display panel and improves the display quality of the organic light emitting display. In addition, a switch circuit can be disposed in the drive circuit so that the operational amplifier OA can automatically switches to the comparator circuit during the calibration period. The offset voltage adjustment unit can be built-in in the operational amplifier OA without the need of placing additional compensation circuits like the conventional compensating circuit. So that, the chip area of the drive circuit can be effectively saved, and errors generated by the additional comparison circuits can be eliminated. Thereby, improve the calibration accuracy and reduce overall power consumption of the drive circuit

The above-mentioned descriptions represent merely the exemplary embodiment of the instant disclosure, without any intention to limit the scope of the instant disclosure thereto. Various equivalent changes, alternations or modifications based on the claims of instant disclosure are all consequently viewed as being embraced by the scope of the instant disclosure.

What is claimed is:

1. A drive circuit, adapted for driving an organic light emitting display (OLED), the driving circuit comprising:
a digital-to-analog conversion unit;
a control unit, coupled to the digital-to-analog conversion unit; and
an output unit having a plurality of buffer units, each of the buffer unit comprising:
an operational amplifier having a differential input stage, a bias stage, an output stage, and an offset voltage adjustment unit, wherein the offset voltage adjustment unit comprises a resistor string and a plurality of latch units coupled to the resistor string, the offset voltage adjustment unit being coupled between the bias stage and a ground, the offset voltage adjustment unit is configured for adjusting a bias current generated by the bias stage; and
a calibration unit, coupled to the latching units and an output terminal of the operational amplifier, the calibration unit operatively controlling operations of the latch units to adjust the bias current of the bias stage according to an output voltage of the operational amplifier;
wherein, the control unit inserts a calibration period in a driving cycle, during which the control unit enables the calibration unit to perform a calibration procedure, and the calibration unit operatively causes the latch units to enter a latch state to calibrate an output offset voltage of the operational amplifier at the completion of the calibration procedure.

2. The drive circuit according to claim 1, wherein the resistor string has a first-end and a second-end, the first-end and the second-end are respectively coupled to the bias stage, and a plurality of resistors series-connected between the firs-end and the second-end form a plurality of junctions, wherein the latch units are coupled between the junction points and the ground, respectively; wherein the calibration unit sequentially conducts the latch units to adjust the bias current during the calibration period so as to calibrate the output offset voltage of the operational amplifier.

3. The drive circuit according to claim 2, wherein when the calibration unit detects that the output voltage of the operational amplifier changes from a high voltage level to a low voltage level or from a low voltage level to a high voltage level, the calibration unit outputs a latch signal causing the latch units to enter the latch state so that one of the latch units selected maintains conduction.

4. The drive circuit according to claim 1, wherein the calibration unit comprises:
a detection unit, coupled the output terminal of the operational amplifier and configured for operatively detecting the output voltage of the operational amplifier; and
a latch control circuit, coupled the detection unit and the latch units, the latch control circuit sequentially conducting the latch units according to the detection result of the detection unit until the output voltage of the operational amplifier undergoes a logic level change during the calibration procedure and causing the latch units to enter the latch state so that one of the latch units selected maintain conduction at the completion of the calibration procedure.

5. The drive circuit according to claim 2, wherein the latch unit comprises:
a first transistor, a source of the first transistor coupled to the control unit, a gate of the first transistor being controlled by the calibration unit;
a second transistor, a drain of the second transistor coupled to the junctions formed between the resistors, a source of the second transistor coupled to the ground, a gate of the second transistor coupled to a drain of the first transistor; and
a storage capacitor, coupled between the gate of the second transistor and the ground.

6. The drive circuit according to claim 5, wherein the calibration unit sequentially turns on the first transistor of each latch unit to charge the storage capacitor causing the second transistor to turn on to adjust the bias current during the calibration procedure; when the calibration unit detects that the output voltage of the operational amplifier undergoes a logic level change, the calibration unit turns off the first transistor to have the second transistor of one of the latch units selected maintaining conduction while the second transistors of the other latch units being turned off causing the latching units to enter the latch state.

7. The drive circuit according to claim 1, wherein the driving cycle comprises at least one driving period and at least one calibration period, during the driving period, the control unit operatively controlling each of the buffer units of the output unit to output a gray level voltage according to an image data causing the OLED to correspondingly display an image.

8. The drive circuit according to claim 7, wherein the control unit inserts the calibration period in a time interval between two adjacent driving periods.

9. The drive circuit according to claim 7, wherein the buffer unit comprises
a first switch, coupled between a non-inverting input terminal of the operational amplifier and an inverting input terminal of the operational amplifier; and
a second switch, coupled between the inverting input terminal of the operational amplifier and the output terminal of the operational amplifier; and
a third switch, coupled between the output terminal of the operational amplifier and a OLED display panel of the OLED;
wherein the control unit turns on the first switch, while turns off the second switch and the third switch during the calibration period to calibrate the output offset voltage of the operational amplifier according to the output voltage of the operational amplifier; wherein the control unit simultaneously turns on the second switch and the third switch while turns off the first switch during the driving period to have the operational amplifier outputting the gray level voltage to the OLED display panel of the OLED.

10. An offset voltage adjustment unit, adapted for an operational amplifier, the operational amplifier having a differential input stage, a bias stage, and an output stage, the offset voltage adjustment unit being coupled to the bias stage and a ground, the offset voltage adjustment unit comprising:
a resistor string having a first-end and a second-end, the first-end and the second-end being respectively coupled to the bias stage, a plurality of resistors series-connected between the first-end and the second-end forming a plurality of junctions; and
a plurality of latch units, coupled between the junctions and the ground respectively, the latch units being configured to sequentially conduct responsive to a control signal to adjust a bias current generated by the bias stage and to enter a latch state upon receiving a latch signal so as to calibrate an output offset voltage of the operational amplifier.

11. The offset voltage adjustment unit according to claim 10, wherein when the latch units enter the latch state, only one of the latch units being selected maintains conduction, while others latch units turn off to calibrate the output offset voltage of the operational amplifier.

12. The offset voltage adjustment unit according to claim 10, wherein the latch units comprise:
a first transistor, a source of the first transistor being configured to receive the control signal, while a gate of the first transistor being configured to receive the latch signal;
a second transistor, a drain of the second transistor coupled to the junctions formed between the resistors, a source of the second transistor coupled to the ground, a gate of the second transistor coupled to the drain of the first transistor; and
a storage capacitor, coupled between the gate of the second transistor and the ground.

13. The offset voltage adjustment unit according to claim 12, wherein when the first transistor of each latch units receives the control signal, the first transistor of the respective latch unit is turned on to charge the storage capacitor and causes the second transistor to turn on to adjust the bias current; when the gate of the first transistor of the latch units receives the latch signal, the first transistor turns off to have the second transistor of one of the latch units selected maintaining conduction, while the second transistor of the other latch units being turned off causing the latching units to enter the latch state.

14. The offset voltage adjustment unit according to claim 10, wherein the offset voltage adjustment unit is coupled to a calibration unit to receive the latch signal, and the calibration unit comprises:
a detection unit, coupled the output terminal of the operational amplifier and the control unit, operatively detecting the output voltage of the operational amplifier; and
a latch control circuit, coupled to the detection unit and the latch units, the latch control circuit sequentially causes one of the latch units to conduct according to the detection result of the detection unit until the output voltage of the operational amplifier undergoes a logic level change, wherein when the latch control circuit operatively detects that the output voltage of the operational amplifier undergoes the logic level change, the latch control circuit outputting the latch signal to cause the latch units to enter the latch stage so that one of the latch units selected maintain conduction.
